(19) United States
(12) Patent Application Publication
(10) Pub. No.: US 2025/0048554 A1
(43) Pub. Date: Feb. 6, 2025

(54) FLEXIBLE PRINTED CIRCUIT ROGOWSKI COIL

(71) Applicant: Littelfuse Europe GmbH, Bremen (DE)

(72) Inventors: Pavel Kucera, Bremen (DE); Ludwig Brabetz, Kassel (DE); Mohamed Ayeb, Kassel (DE); Markus Horn, Kassel (DE)

(73) Assignee: Littelfuse Europe GmbH, Bremen (DE)

(21) Appl. No.: 18/792,719

(22) Filed: Aug. 2, 2024

(30) Foreign Application Priority Data
Aug. 4, 2023 (EP) 23189752.1

(51) Int. Cl. H05K 1/16; G01R 15/18; H01F 5/00; H05K 1/02; H05K 3/32

(52) U.S. Cl. CPC H05K 1/165; G01R 15/181; H01F 5/003; H05K 1/028; H05K 3/32

(57) ABSTRACT

A flexible printed circuit Rogowski coil is provided and can include a flexible printed circuit board, a first connector disposed proximate a first end of the flexible printed circuit board, a second connector disposed proximate the first end of the flexible printed circuit board, a first portion of an air coil printed as a first pattern a top side of the flexible printed circuit board and connected to the first connector, and a second portion of the air coil printed as a second pattern on a bottom side of the flexible printed circuit board and connected to the second connector, the second pattern corresponding to the first pattern.

### CROSS-REFERENCE TO RELATED APPLICATIONS

This application claims the benefit of priority to European Patent Application No. 23189752.1, filed Aug. 4, 2023, entitled “FLEXIBLE PRINTED CIRCUIT ROGOWSKI COIL,” which application is incorporated herein by reference in its entirety.

### FIELD

The present disclosure generally relates to circuit protection devices and devices for measuring electrical current. More particularly, the present disclosure relates to a flexible printed circuit Rogowski coil.

### BACKGROUND

A Rogowski coil is an electrical apparatus that can be used for quantitatively and qualitatively measuring alternating current (AC) or high-speed transient or pulsing current by using both Ampere's law and Faraday's law. As seen in FIG. 1, a known Rogowski coil 100 can include an air coil 102 for measuring current passing through a conductor 104. The air coil 102 can include a toroid, helical coil with N turns and a cross-sectional area A. As seen, an end of a wire forming the air coil 102 can return through a center of the air coil 102 to a beginning of the wire so that both terminals 106 of the air coil 102 are on one side of the air coil 102. Such a configuration allows the air coil 102 to span only intended surfaces of the turns in the air coil 102, nothing more, while also wrapping around an entire circumference of the conductor 104 being measured without physically interrupting the conductor 104.

Voltage generated at the terminals 106 is governed by Faraday's law of induction as follows:

$$v ( t ) = - k \frac{di ( t )}{dt} \qquad ( 1 )$$

where k is a proportionality constant reflecting a configuration of the air coil 102 and can depend on physical dimensions A, N, and r of the air coil 102, where A is the cross-sectional area of each of the turns in the air coil 102, N is a number of the turns in the air coil 102, and r is a radius of the air coil 102. A signal processing circuit 108 connected to the terminals 106 measures the voltage across the terminals 106 v(t). Then, the current i(t) passing through the conductor 104 is derived from the voltage v(t) by integrating equation 1. The integrator can be realized using either passive or active discrete components or by a numerical integration in a computer.

Using the Rogowski coil 100 to measure the current i(t) in the conductor 104 has many advantages when compared to other known methods to measure current. First, because the air coil 102 is used with no magnetic core, there are no problems with saturating a core when there is an accidental short circuit in the conductor circuit. Second, a frequency response of the air coil 102 is only limited by dimensions of the air coil 102 and capabilities of the signal processing circuit 108. Next, both of the terminals 106 on the same side of the air coil 102 provides for non-intrusive installation. In particular, the air coil 102 can be flexibly wrapped around the conductor 104, including a wire, isolated wire, busbar, and the like, without intercepting the conductor 104. Furthermore, the air coil 102 is naturally galvanically isolated from the conductor 104, and internal impedance of the air coil 102 is very low, which increases signal-to-noise ratio immunity. If the turns in the air coil 102 are identical and evenly spaced, then the voltage v(t) output is proportional to a derivative of the current i(t) passing through the conductor 104, thereby eliminating all external electromagnetic fields not generated by the conductor 104. Finally, positioning and orientation of the conductor 104 have negligible impact on measurement.

While possessing many advantages, it is impractical to design and use a Rogowski coil known in the art because of several limitations on a practical realization thereof. First, wiring the air coil 102 as shown in FIG. 1 is mechanically complicated and expensive in mass production. Furthermore, it is difficult to achieve evenly spaced and identical turns in the air coil 102. A nonmagnetic supporting core can be used to assist in achieving the evenly spaced and identical turns, but doing so decreases flexibility of the air coil 102 while simultaneously increasing dimensions and costs thereof. However, without the supporting core, a wire must have a large enough cross-sectional area to achieve a self-supporting configuration, but such a wire is usually expensive and inflexible, again decreasing the flexibility of the air coil 102 while simultaneously increasing the cost of the air coil 102.

In view of the above, there is a continuing, ongoing need for an improved Rogowski coil.

### BRIEF SUMMARY

This Brief Summary is provided to introduce a selection of concepts in a simplified form that are further described below in the Detailed Description. This Brief Summary is not intended to identify key features or essential features of claimed subject matter or intended as an aid in determining scope of the claimed subject matter.

In some embodiments, an apparatus in accordance with the present disclosure can include a flexible printed circuit board, a first connector disposed proximate a first end of the flexible printed circuit board, a second connector disposed proximate the first end of the flexible printed circuit board, a first portion of an air coil printed as a first pattern on a top side of the flexible printed circuit board and connected to the first connector, and a second portion of the air coil printed as a second pattern on a bottom side of the flexible printed circuit board and connected to the second connector, the second pattern corresponding to the first pattern.

In some embodiments, the first portion of the air coil can include a first plurality of coils, each of the first plurality of coils being separated from and electrically connected to one another, and the second portion of the air coil can include a second plurality of coils, each of the second plurality of coils being separated from and electrically connected to one another.

In some embodiments, the first plurality of coils can be equal in number to the second plurality of coils.

In some embodiments, the first plurality of coils can be vertically aligned with the second plurality of coils.

In some embodiments, the first portion of the air coil can be connected to the second portion of the air coil through a respective via located at a respective center of each of the first and second pluralities of coils.

In some embodiments, each of the first plurality of coils can wind in a first direction, and each of the second plurality of coils can wind in the first direction.

In some embodiments, each of the first and second pluralities of coils can include an equal number of turns.

In some embodiments, an electromotive force in each of the first and second pluralities of coils can be induced by a magnetic field generated by a conductor around which the flexible printed circuit board is wrapped, and a voltage v(t) measured across the first connector and the second connector can be a sum of a respective contribution of each of the first and second pluralities of coils.

In some embodiments, each of the first plurality of coils can be connected in series, and each of the second plurality of coils can be connected in series.

In some embodiments, a current i(t) flowing through the conductor can be derived from the voltage v(t) by integrating

$$v ( t ) = - k \frac{di ( t )}{dt} ,$$

where k is a proportionality constant that can depend on physical dimensions A, N, and r of each of the first and second pluralities of coils, where A is a respective cross-sectional area of each of the turns, N is a number of the turns, and r is a respective radius of each of the first and second pluralities of coils.

In some embodiments, the apparatus can include a plastic holder supporting the flexible printed circuit board so that each of the first and second pluralities of coils is perpendicular to a magnetic field generated by a conductor passing through a center hole of the plastic holder.

In some embodiments, a plurality of bend columns can protrude from a top surface of the plastic holder, and the flexible printed circuit board can be wound around the plurality of bend columns.

In some embodiments, a plurality of spacing holes can be distributed along a length of the flexible printed circuit board, and a plurality of spacing nodes can protrude from at least some of the plurality of bend columns, wherein each of the plurality of spacing holes can fit around a respective one of the plurality of spacing nodes to secure the flexible printed circuit board in position.

In some embodiments, a method in accordance with the present disclosure can include printing a first portion of an air coil as a first pattern on a top side of a flexible printed circuit board, connecting the first portion of the air coil to a first connector disposed proximate a first end of the flexible printed circuit board, printing a second portion of the air coil as a second pattern on a bottom side of the flexible printed circuit board, the second pattern corresponding to the first pattern, connecting the second portion of the air coil to a second connector disposed proximate the first end of the flexible printed circuit board, and winding the flexible printed circuit board around a plurality of bend columns protruding from a top surface of a plastic holder so that the first portion of the air coil and the second portion of the air coil are perpendicular to a magnetic field generated by a conductor passing through a center hole of the plastic holder.

In some embodiments, the method can include physically separating a first plurality of coils in the first portion of the air coil from one another, electrically connecting the first plurality of coils to each other in series, physically separating a second plurality of coils in the second portion of the air coil from one another, and electrically connecting the second plurality of coils to each other in series.

In some embodiments, the method can include vertically aligning the first plurality of coils with the second plurality of coils.

In some embodiments, the method can include connecting the first portion of the air coil to the second portion of the air coil through a respective via located at a respective center of each of the first and second pluralities of coils.

In some embodiments, the method can include inducing an electromotive force in each of the first and second pluralities of coils by a magnetic field generated by the conductor and measuring a voltage v(t) across the first connector and the second connector, wherein the voltage v(t) is a sum of a respective contribution of each of the first and second pluralities of coils.

In some embodiments, a current i(t) flowing through the conductor can derived from the voltage v(t) by integrating

$$v ( t ) = - k \frac{di ( t )}{dt} ,$$

where k is a proportionality constant that can depend on physical dimensions A, N, and r of each of the first and second pluralities of coils, where A is a respective cross-sectional area of each turn in the first and second pluralities of coils, N is a number of turns in each of the first and second pluralities of coils, and r is a respective radius of each of the first and second pluralities of coils.

In some embodiments, the method can include fitting each of a plurality of spacing holes distributed along a length of the flexible printed circuit board around a respective one of a plurality of spacing nodes protruding from at least some of the plurality of bend columns to secure the flexible printed circuit board in position.

Other technical features may be readily apparent to one skilled in the art from the following figures, descriptions, and claims.

### BRIEF DESCRIPTION OF THE SEVERAL VIEWS OF THE DRAWINGS

FIG. 1 is a perspective view illustrating a Rogowski coil know in the art;

FIG. 2A is a top view illustrating a flexible printed circuit Rogowski coil in accordance with disclosed embodiments;

FIG. 2B is a bottom view illustrating a flexible printed circuit Rogowski coil in accordance with disclosed embodiments;

FIG. 3A is a perspective view illustrating a plastic holder in accordance with disclosed embodiments;

FIG. 3B is a perspective view illustrating a plastic holder with a flexible printed circuit Rogowski coil supported thereon in accordance with disclosed embodiments; and

FIG. 4 is a flow diagram illustrating a method in accordance with disclosed embodiments.

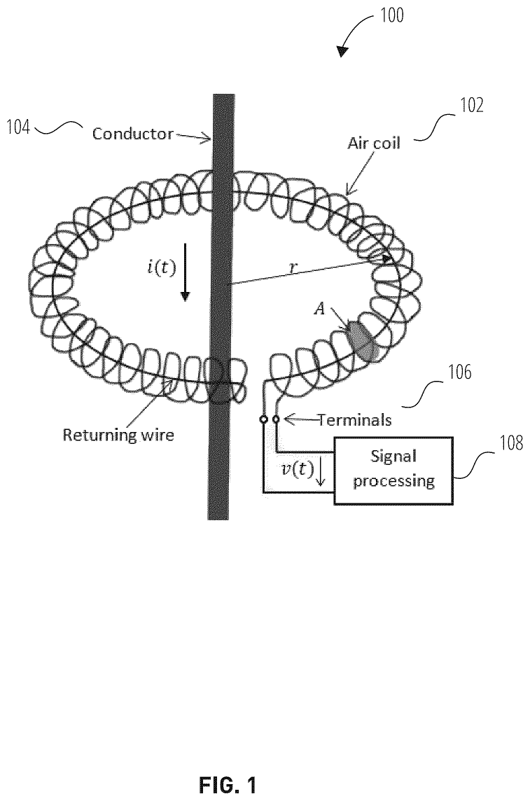

### DETAILED DESCRIPTION

Exemplary embodiments of a flexible printed circuit Rogowski coil in accordance with the present disclosure will now be described more fully hereinafter with reference made to the accompany drawings. The flexible printed circuit Rogowski coil may, however, be embodied in many different forms and should not be construed as being limited to the embodiments set forth herein. Rather, these embodiments are provided so that this disclosure will convey certain exemplary aspects of a flexible printed Rogowski coil to those skilled in the art.

As disclosed herein, the flexible printed circuit Rogowski coil can be used for quantitatively and qualitatively measuring AC or high-speed transient or pulsing current flowing through a conductor. Advantageously, the flexible printed circuit Rogowski coil disclosed herein can be suitable for mass production in a cost-effective manner as compared to wired coil production.

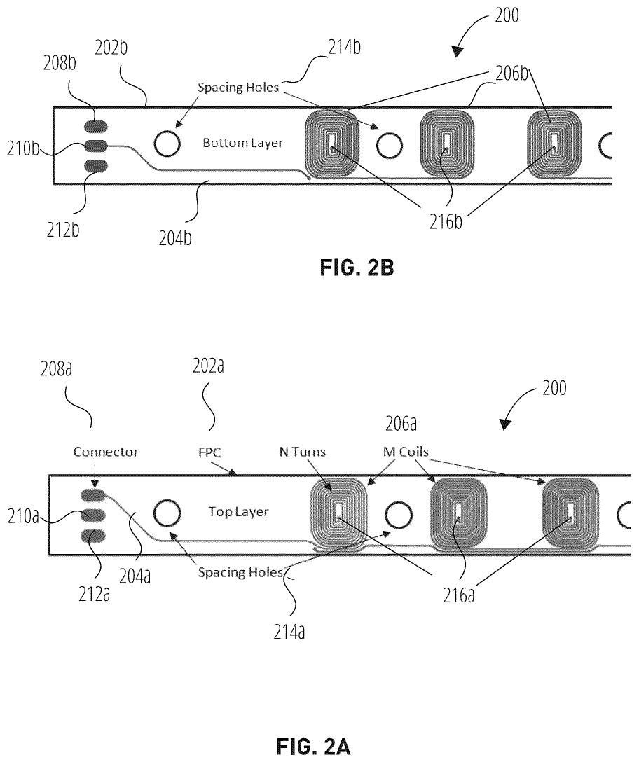

FIG. 2A is a top view of the flexible printed circuit (FPC) Rogowski coil 200 in accordance with disclosed embodiments, and FIG. 2B is a bottom view of the flexible printed circuit Rogowski coil 200 in accordance with disclosed embodiments. As seen, in some embodiments, the flexible printed circuit Rogowski coil 200 can include a flexible printed circuit board 202a, 202b, a first portion of an air coil 204a, a second portion of the air coil 204b, a first connector 208a, 208b, a second connector 210a, 210b, a third connector 212a, 212b, and a plurality of spacing holes 214a, 214b. In some embodiments, the flexible printed circuit board 202a, 202b can be double sided, and in some embodiments, the flexible printed circuit board 202a, 202b can be thin, for example, approximately 25 μm thick. Furthermore, in some embodiments, the flexible printed circuit board 202a, 202b can include a copper clad laminate. Advantageously, printing on copper clad laminate can produce distances between traces of the air coils 204a, 204b as small as 100 μm.

In some embodiments, the first connector 208a, 208b can be disposed proximate a first end of the flexible printed circuit board 202a, 202b, and the second connector 210a, 210b can be disposed proximate the first end of the flexible printed circuit board 202a, 202b. That is, the first connector 208a, 208b and the second connector 210a, 210b can be disposed proximate the same end of the flexible printed circuit board 202a, 202b. Advantageously, placing all of the connectors 208a, 208b, 210a, 210b 212a, 212b proximate the same end of the flexible printed circuit board 202a, 202b can facilitate a nonintrusive installation of the flexible printed circuit Rogowski coil 200.

In some embodiments, the first portion of the air coil 204a can be realized, for example, printed, as a first pattern on a top side of the flexible printed circuit board 202a and connected to the first connector 208a, 208b. Similarly, in some embodiments, the second portion of the air coil 204b can be realized, for example, printed, as a second pattern on a bottom side of the flexible printed circuit board 202b and connected to the second connector 210a, 210b.

In some embodiments, the first portion of the air coil 204a can include a first plurality of coils 206a, and each of the first plurality of coils 206a can be physically separated from and electrically connected to one another. Similarly, in some embodiments, the second portion of the air coil 204b can include a second plurality of coils 206b, and each of the second plurality of coils 206b can be physically separated from and electrically connected to one another. In some embodiments, each of the first plurality of coils 206a can be connected in series, and each of the second plurality of coils 206b can be connected in series.

In some embodiments, the second pattern of the second portion of the air coil 204b can correspond to the first pattern of the first portion of the air coil 204a. For example, in some embodiments, the first plurality of coils 206a can be equal in number to the second plurality of coils 206b. That is, in some embodiments, the first plurality of coils 206a can include M coils, and the second plurality of coils 206b can include M coils. In some embodiments, the first plurality of coils 206a can be vertically aligned with the second plurality of coils 206b. Furthermore, in some embodiments, each of the first plurality of coils 206a can wind in a first direction, and each of the second plurality of coils 206b can wind in the first direction. That is, a winding direction (the first direction) of the first plurality of coils 206a and the second plurality of coils 206b can be the same. In some embodiments, each of the first and second pluralities of coils 206a, 206b can include an equal number of turns. That is, in some embodiments, each of the first plurality of coils 206a can include N turns, and each of the second plurality of coils 206b can include N turns.

In some embodiments, the first portion of the air coil 204a can be connected to the second portion of the air coil 204b through a respective via 216a, 216b located at a respective center of each of the first and second pluralities of coils.

In some embodiments, the plurality of spacing holes 214a, 214b can be distributed along a length of the flexible printed circuit board 202a, 202b. For example, in some embodiments, the plurality of spacing holes 214a, 214b can be interspersed with the plurality of coils 206a, 206b along the length of the flexible printed circuit board 202a, 202b.

In accordance with disclosed embodiments, the flexible printed circuit Rogowski coil 200 can be scalable and fully configurable. For example, the first pattern of the first portion of the air coil 204a and the second pattern of the second portion of the air coil 204b can be changed, for example, with CAD tools, as needed to achieve any desired parameter of the first and second plurality of coils 206a, 206b. In this regard, at least the following parameters can be configured: thicknesses of the traces of the air coils 204a, 204b, distances of and between the traces of the air coils 204a, 204b, a number of turns (N) in the first and second pluralities of coils 206a, 206b, a number of coils (M) in the first and second pluralities of coils 206a, 206b, dimensions of the first and second pluralities of coils 206a, 206b, and the like.

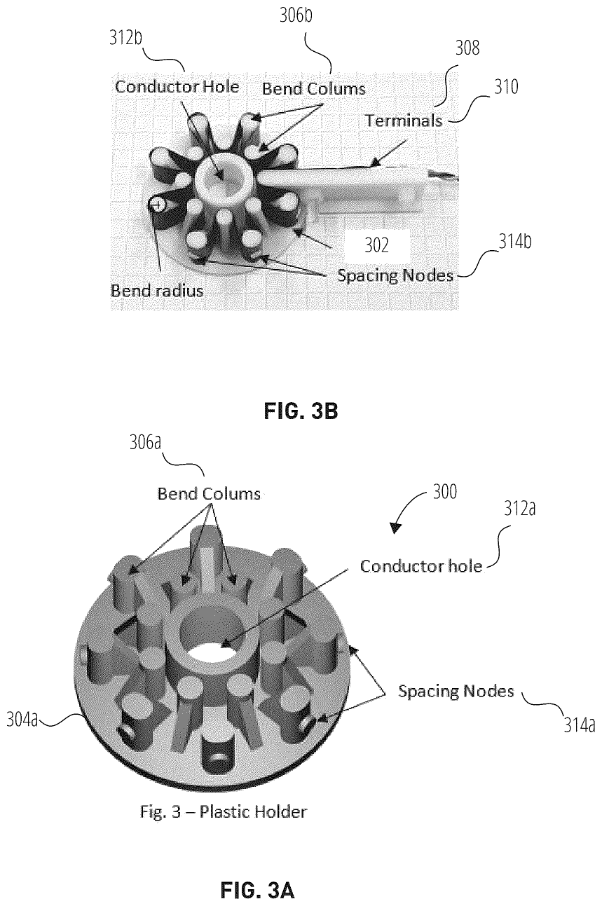

FIG. 3A is a perspective view of a plastic holder 300 in accordance with disclosed embodiments. As seen, in some embodiments, the plastic holder 300 can include a flat disc 304a, a plurality of bend columns 306a protruding, for example, in a perpendicular direction, from a top surface of the flat disc 304a, and a center hole 312a. In some embodiments, a first set of the plurality of bend columns 306a can form a first ring with a first radius around the center hole 312a, and a second set of the plurality of bend columns 306a can form a second ring with a second radius that is larger than the first radius around the center hole 312a. In some embodiments, a plurality of spacing nodes 314a can protrude from an outward facing side of at least some of the plurality of bend columns 306a, for example, from each of the second set of the plurality of bend columns 306a.

In some embodiments, the plastic holder 300 can be formed from any low-cost plastic material, and in some embodiments, the plastic holder 300 can be mass produced with plastic extrusion machinery.

As seen in FIG. 3B, in some embodiments, the plastic holder 300 can support a flexible printed circuit Rogowski coil 302 thereon, for example, the flexible printed circuit Rogowski coil 200. In some embodiments, the flexible printed circuit Rogowski coil 302 can be wound around the plurality of bend columns 306b for simple assembly. Advantageously, the plurality of bend columns 306b can ensure that a bending radius of the flexible printed circuit Rogowski coil 302 is above a minimum radius allowed for a material of the flexible printed circuit Rogowski coil 302. Furthermore, in some embodiments, each of a plurality of spacing holes of the flexible printed circuit Rogowski coil 302, for example, the plurality of spacing holes 214a, 214b, can fit around a respective one of the plurality of spacing nodes 314b to secure the flexible printed circuit Rogowski coil 302 in position. Advantageously, the plurality of spacing nodes 314b can ensure an even and symmetrical distribution of a first and second pluralities of coils of the flexible printed circuit Rogowski coil 302, for example, the first and second pluralities of coils 206a, 206b, around a circumference of the plastic holder 300.

In some embodiments, the plastic holder 300 can support the flexible printed circuit Rogowski coil 302 in a configuration that ensures each of the first and second pluralities of coils is perpendicular to a magnetic field generated by a conductor passing through the center hole 308 of the plastic holder 300.

In some embodiments, an electromotive force in each of the first and second pluralities of coils can be induced by a magnetic field generated by the conductor passing through the center hole 308, and a voltage v(t) measured across terminals 308, 310, for example, the first connector 208a, 208b and the second connector 210a, 210b, can be a sum of a respective contribution of each of the first and second pluralities of coils. In some embodiments, a direction of flow of the electromotive force can be equivalent to a winding direction of the first and second pluralities of coils.

In some embodiments, a current i(t) flowing through the conductor can be derived from the voltage v(t) by integrating

$$v ( t ) = - k \frac{di ( t )}{dt} ,$$

where k is a proportionality constant that can depend on physical dimensions A, N, and r of each of the first and second pluralities of coils, where A is a respective cross-sectional area of each of the turns in the first and second pluralities of coils, N is a number of the turns in each of the first and second pluralities of coils, and r is a respective radius of each of the first and second pluralities of coils. Because the material of the flexible printed circuit Rogowski coil 302 is thin, the first and second pluralities of coils can be close enough together to effectively attenuate any electromagnetic interference cutting the first and second pluralities of coils.

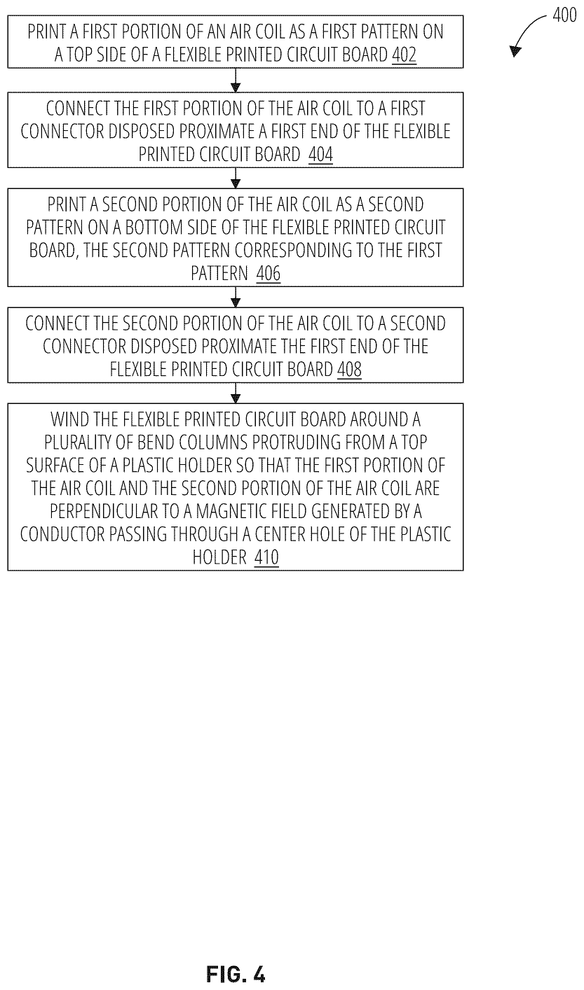

FIG. 4 is a flow diagram of a method 400 in accordance with disclosed embodiments. As seen, in some embodiments, the method 400 can include printing the first portion of the air coil 204a as the first pattern on a top side of the flexible printed circuit board 202a as in 402 and connecting the first portion of the air coil 204a to the first connector 208a disposed proximate the first end of the flexible printed circuit board 202a as in 404. The method 400 can also include printing the second portion of the air coil 204b as the second pattern on a bottom side of the flexible printed circuit board 202b as in 406 and connecting the second portion of the air coil 204b to the second connector 210b disposed proximate the first end of the flexible printed circuit board 202b as in 408. In some embodiments, the second pattern can correspond to the first pattern.

In some embodiments, printing the first portion of the air coil 204a as the first pattern on the top side of the flexible printed circuit board 202a as in 402 can include physically separating the first plurality of coils 206a in the first portion of the air coil 204a from one another and electrically connecting the first plurality of coils 206a to each other in series. Similarly, in some embodiments, printing the second portion of the air coil 204b as the second pattern on the bottom side of the flexible printed circuit board 202b as in 406 can include physically separating the second plurality of coils 206b in the second portion of the air coil 204b from one another and electrically connecting the second plurality of coils 206b to each other in series. In some embodiments, the method 400 can include vertically aligning the first plurality of coils 206a with the second plurality of coils 206b, and in some embodiments, the method 400 can include connecting the first portion of the air coil 204a to the second portion of the air coil 204b through a respective via 216a, 216b located at a respective center of each of the first and second pluralities of coils 206a, 206b.

Next, the method 400 can include winding the flexible printed circuit board 202a, 202b around the plurality of bend columns 306a, 306b of the plastic holder 300 so that the first portion of the air coil 204a and the second portion of the air coil 204b are perpendicular to the magnetic field generated by the conductor passing through the center hole 312a, 312b of the plastic holder 300 as in 410. For example, in some embodiments, the method 400 can include fitting each of the plurality of spacing holes 214a, 214b distributed along the length of the flexible printed circuit board 202a, 202b around a respective one of the plurality of spacing nodes 314a, 314b protruding from at least some of the plurality of bend columns 306a, 306b to secure the flexible printed circuit board 202a, 202b in position.

In some embodiments, when the current is flowing through the conductor, the method 400 can include inducing the electromotive force in each of the first and second pluralities of coils 206a, 206b by the magnetic field generated by the conductor and measuring the voltage v(t) across the first connector 208a, 208b and the second connector 210a, 210b, wherein the voltage v(t) is a sum of a respective contribution of each of the first and second pluralities of coils 206a, 206b.

In some embodiments, the current i(t) flowing through the conductor can be derived from the voltage v(t) by integrating

$$v ( t ) = - k \frac{di ( t )}{dt} ,$$

where k is a proportionality constant that can depend on physical dimensions A, N, and r of each of the first and second pluralities of coils 206a, 206b, where A is a respective cross-sectional area of each of the turns in the first and second pluralities of coils 206a, 206b, N is a number of the turns in each of the first and second pluralities of coils 206a, 206b, and r is a respective radius of each of the first and second pluralities of coils 206a, 206b.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

While the present disclosure makes reference to certain embodiments, numerous modifications, alterations and changes to the described embodiments are possible without departing from the sphere and scope of the present disclosure, as defined in the appended claims. Accordingly, it is intended that the present disclosure not be limited to the described embodiments, but that it has the full scope defined by the language of the following claims and equivalents thereof.

1. An apparatus comprising:
a flexible printed circuit board;
a first connector disposed proximate a first end of the flexible printed circuit board;
a second connector disposed proximate the first end of the flexible printed circuit board;
a first portion of an air coil printed as a first pattern on a top side of the flexible printed circuit board and connected to the first connector; and
a second portion of the air coil printed as a second pattern on a bottom side of the flexible printed circuit board and connected to the second connector, the second pattern corresponding to the first pattern.

2. The apparatus of claim 1 wherein the first portion of the air coil includes a first plurality of coils, each of the first plurality of coils being separated from and electrically connected to one another, and wherein the second portion of the air coil includes a second plurality of coils, each of the second plurality of coils being separated from and electrically connected to one another.

3. The apparatus of claim 2 wherein the first plurality of coils is equal in number to the second plurality of coils.

4. The apparatus of claim 3 wherein the first plurality of coils is vertically aligned with the second plurality of coils.

5. The apparatus of claim 4 wherein the first portion of the air coil is connected to the second portion of the air coil through a respective via located at a respective center of each of the first and second pluralities of coils.

6. The apparatus of claim 2 wherein each of the first plurality of coils winds in a first direction, and wherein each of the second plurality of coils winds in the first direction.

7. The apparatus of claim 2 wherein each of the first and second pluralities of coils includes an equal number of turns.

8. The apparatus of claim 7 wherein, an electromotive force in each of the first and second pluralities of coils is induced by a magnetic field generated by a conductor around which the flexible printed circuit board is wrapped, and wherein a voltage v(t) measured across the first connector and the second connector is a sum of a respective contribution of each of the first and second pluralities of coils.

9. The apparatus of claim 8 wherein each of the first plurality of coils is connected in series, and wherein each of the second plurality of coils is connected in series.

10. The apparatus of claim 8 wherein a current i(t) flowing through the conductor is derived from the voltage v(t) by integrating
$$v ( t ) = - k \frac{di ( t )}{dt} ,$$
where k is a proportionality constant dependent on physical dimensions A, N, and r of each of the first and second pluralities of coils, where A is a respective cross-sectional area of each of the turns, N is a number of the turns, and r is a respective radius of each of the first and second pluralities of coils.

11. The apparatus of claim 2 further comprising:
a plastic holder supporting the flexible printed circuit board so that each of the first and second pluralities of coils is perpendicular to a magnetic field generated by a conductor passing through a center hole of the plastic holder.

12. The apparatus of claim 11 further comprising:
a plurality of bend columns protruding from a top surface of the plastic holder,
wherein the flexible printed circuit board is wound around the plurality of bend columns.

13. The apparatus of claim 12 further comprising:
a plurality of spacing holes distributed along a length of the flexible printed circuit board; and
a plurality of spacing nodes protruding from at least some of the plurality of bend columns,
wherein each of the plurality of spacing holes fits around a respective one of the plurality of spacing nodes to secure the fixed printed circuit board in position.

14. A method comprising:
printing a first portion of an air coil as a first pattern on a top side of a flexible printed circuit board;
connecting the first portion of the air coil to a first connector disposed proximate a first end of the flexible printed circuit board;
printing a second portion of the air coil as a second pattern on a bottom side of the flexible printed circuit board, the second pattern corresponding to the first pattern;
connecting the second portion of the air coil to a second connector disposed proximate the first end of the flexible printed circuit board; and
winding the flexible printed circuit board around a plurality of bend columns protruding from a top surface of a plastic holder so that the first portion of the air coil and the second portion of the air coil are perpendicular to a magnetic field generated by a conductor passing through a center hole of the plastic holder.

15. The method of claim 14 further comprising:
physically separating a first plurality of coils in the first portion of the air coil from one another;
electrically connecting the first plurality of coils to each other in series;
physically separating a second plurality of coils in the second portion of the air coil from one another; and
electrically connecting the second plurality of coils to each other in series.

16. The method of claim 15 further comprising:
vertically aligning the first plurality of coils with the second plurality of coils.

17. The method of claim 15 further comprising:
connecting the first portion of the air coil to the second portion of the air coil through a respective via located at a respective center of each of the first and second pluralities of coils.

18. The method of claim 15 further comprising:
inducing an electromotive force in each of the first and second pluralities of coils by a magnetic field generated by the conductor; and
measuring a voltage v(t) across the first connector and the second connector,
wherein the voltage v(t) is a sum of a respective contribution of each of the first and second pluralities of coils.

19. The method of claim 18 wherein a current i(t) flowing through the conductor is derived from the voltage v(t) by integrating
$$v ( t ) = - k \frac{di ( t )}{dt} .$$
where k is a proportionality constant dependent on physical dimensions A, N, and r of each of the first and second pluralities of coils, where A is a respective cross-sectional area of each turn in the first and second pluralities of coils, N is a number of turns in each of the first and second pluralities of coils, and r is a respective radius of each of the first and second pluralities of coils.

20. The method of claim 14 further comprising:
fitting each of a plurality of spacing holes distributed along a length of the flexible printed circuit board around a respective one of a plurality of spacing nodes protruding from at least some of the plurality of bend columns to secure the fixed printed circuit board in position.
